(19) United States
(12) Patent Application Publication
(10) Pub. No.: US 2015/0301148 A1
(43) Pub. Date: Oct. 22, 2015

(54) Method for Checking an Electrical Current Measurement, Circuit for Carrying Out the Method, Battery and Motor Vehicle

(71) Applicants: Robert Bosch GmbH, Stuttgart (DE); Samsung SDI Co., Ltd., Yongin-si, Gyeonggi-do (KR)

(72) Inventor: Patrick Kaupp, Stuttgart (DE)

(21) Appl. No.: 14/365,056

(22) PCT Filed: Nov. 14, 2012
(86) PCT No.: PCT/EP2012/072535

§ 371 Date: Jun. 12, 2014

(30) Foreign Application Priority Data
Dec. 14, 2011 (DE) 10 2011 088 590.0

(51) Int. Cl. G01R 35/00; G01R 19/10; G01R 19/00

(52) U.S. Cl. CPC G01R 35/00; G01R 19/0092; G01R 19/10

(57) ABSTRACT

A method for checking an electrical current measurement includes a first step of measuring a current to be measured I_{M} using a current measuring structure. The method also includes a second step of superimposing a test current I_{P} on the current to be measured I_{M} to form a resultant current I_{Res}=I_{M}+I_{P}. The resultant current I_{Res} is measured in a third step using the current measuring structure within a period of time of the second step. In a fourth step, a check follows in order to determine whether the resultant current I_{Res} measured in the third step corresponds to a sum of the current I_{M} measured in the first step plus a known magnitude of the test current I_{P} superimposed in the second step.

The present invention relates to a method for checking an electrical current measurement and to a circuit with which the method for checking an electrical current measurement can be carried out.

The invention also relates to a battery having the circuit according to the invention and to a motor vehicle having the battery according to the invention.

### PRIOR ART

It would appear that, in future, new battery systems will be used both in stationary applications, such as wind turbines, in motor vehicles in the form of hybrid or electric motor vehicles and in electronic devices, such as laptops or mobile telephones, with very stringent requirements being placed on said battery systems in respect of reliability, safety, performance and life.

In vehicles with an at least partially electric drive, electrical energy stores are used in order to store the electrical energy for the electric motor which assists the drive or acts as drive. In vehicles of the most recent generation, in this case so-called lithium-ion batteries are used. These batteries are distinguished, inter alia, by high energy densities and an extremely low level of self-discharge. Lithium-ion cells have at least one positive and one negative electrode (cathode and anode, respectively) which can reversibly insert (intercalation) lithium ions (Li+) or extract (deintercalation) them again.

FIG. 1 shows how individual battery cells 10 can be assembled to give battery modules 12 and then batteries 14. This is performed by poles of the battery cells 10 being connected in parallel or series (not illustrated). In this case, by definition, a battery module 12 or a battery 14 comprises at least two battery cells 10, wherein the terms battery 14 and battery module 12 are often used synonymously. The electric voltage of a battery 14 is, for example, between 120 and 600 volts DC.

In the case of batteries for automobile drive technology (traction batteries), there is a need to determine the state of charge and, for reasons of safety, to measure the current supplied to and from the battery cells. Therefore, the functionality of the current sensor must be known and hence be detectable by means of suitable measures. In many cases, the current is detected using current sensors which operate on the basis of the resistor principle (shunt). Another possibility for detection of an electric current is to use sensors which detect the magnetic field around a conductor, which magnetic field is caused by the flow of current in the conductor, and to infer the flow of current therefrom. In order to enable a redundant measurement, both measurement principles can also be used at the same time, as a result of which the current is measured by means of two different measurement principles.

DE 10 2009 046 564 A1 discloses a battery system having a high-voltage system and a low-voltage system. The high-voltage system comprises a battery module, while the low-voltage system comprises a battery control unit (BCU). Cell-monitoring units are assigned to the battery cells and measure the voltages of the battery cells. Furthermore, the document discloses a redundant current measurement by means of a measuring resistor (shunt) and a Hall sensor.

### DISCLOSURE OF THE INVENTION

The invention provides a method for checking an electrical current measurement. In a first step, an electric current I_{M} to be measured is measured using a means for measuring the current. In a second step, a test current I_{P} is superposed on the electric current I_{M} to be measured to give a resultant current I_{Res}=I_{M}+I_{P}. In a third step, which takes place within the time span of the second step, the resultant current I_{Res} is measured using the means for measuring the current. In a fourth step, a check is performed to ascertain whether the resultant current I_{Res} measured in the third step corresponds to the sum of the current I_{M} measured in the first step and the known magnitude of the test current I_{P} superposed in the second step.

In order that the check performed in the fourth step gives usable results, it should be ensured that the electric current I_{M} to be measured which is measured in the first step has the same magnitude as the current I_{M} to be measured in the second step. For example, this is the case when further information about the current I_{M} to be measured is present, for example whether the current I_{M} to be measured is constant or no current I_{M} (I_{M}=0) to be measured is flowing. In the case of use of the method according to the invention in a motor vehicle, the current I_{M} to be measured is constant, for example, when the motor vehicle is in a stationary state, while no current I_{M} (I_{M}=0) to be measured is flowing before a system whose current I_{M} to be measured is measured transfers to the idle state or when the system is started.

The invention is based on the knowledge of being able to check an electrical current measurement and thus a means for measuring current by superposing a current of known magnitude (test current I_{P}) on a current (current I_{M} to be measured) known from a first measurement. By superposing the two currents, these sum to give a resultant current I_{Res}=I_{M}+I_{P} which is likewise measured in a second measurement. Subsequently, a check is performed to ascertain whether the resultant current I_{Res} measured in the second measurement corresponds to the sum of the current I_{M} to be measured which was measured in the first measurement and the superposed test current I. If this is the case, it is ensured that the means for measuring the current correctly measures differences in a flow of current through a conductor. This response operation can be taken as an indication of the correct operation of the unit; it can thus be assumed that the absolute value of the measurement is also correct.

Therefore, no redundant configuration using a second current sensor is required in order to check the means for measuring current, as a result of which costs can be saved.

During normal operation of the means for measuring the current, the current I_{M} to be measured is measured in accordance with the first step without having a test current I_{P} superposed thereon. If, in accordance with the second and third steps, the test current I_{P} of known magnitude is now to be superposed on the current I_{M} to be measured, then, for example, a current source is used for this purpose, which current source is connected during the second and thus also third steps, while it is disconnected in the first step.

By means of a preferred step of providing a switching means via which the test current I_{P} is conducted in the second and third steps, the means for feeding in current can easily superpose the test current I_{P} on the current I_{M} to be measured. By means of a further preferred step of detecting the switching state of the switching means, a conclusion can then be drawn in respect of the flow of the test current I_{P}. If the switching means is open, no test current I_{P} is flowing; if said switching means is closed, a test current I_{P} is flowing. In this way, the detection of a closed switching means can preferably be used as a trigger for a check according to the fourth step.

Furthermore, an electrical circuit is provided for carrying out the method according to the invention for checking an electrical current measurement. The electrical circuit comprises a means for measuring the current and a current source, wherein the current source is designed to superpose, as required, a test current I_{P} of known magnitude on the current I_{M} to be measured. This is done in such a way that the means for measuring the current can measure a resultant current I_{Res}=I_{M}I_{P}.

The current source can be activated as required, as a result of which a practically constant test current I_{P} is provided and superposed on the current I_{M} to be measured. This is further preferably adjustable, as a result of which the test current I_{P} can be adjusted to the respective requirements, for example as a function of the current I_{M} to be measured. The few components required in addition to the means for measuring the current can easily be integrated into an existing measurement module.

Preferably, a switching means can be connected between the current source and the means for measuring the current, which switching means is further preferably a transistor. In this case, the current source can remain permanently activated; by switching the switching means, for example by means of a control unit, the test current I_{P} can be superposed on the current I_{M} to be measured as required. It can then be inferred from the switching state of the switching means whether or not the test current I_{P} is flowing.

The connectable current source can preferably be implemented by a series circuit composed of a voltage source, a resistor and the switching means. By means of this configuration, a current source with a simple design can be implemented.

According to a preferred configuration of the invention, the current-measuring means is a measuring resistor with an evaluation circuit. The evaluation circuit measures the voltage drop across the measuring resistor which represents a measure for the current flowing through the measuring resistor. In order not to generate any large power losses at the measuring resistor, said resistor is generally dimensioned to be very small so that only small voltage drops occur across the measuring resistor, which voltage drops are amplified by the evaluation circuit.

In addition, a battery is provided comprising the electrical circuit according to the invention. Owing to the simple and inexpensive design of the electrical circuit according to the invention, the costs of the battery can be reduced in comparison with the prior art.

Preferably, the battery is a lithium-ion battery which comprises a plurality of lithium-ion secondary cells. By using lithium-ion technology, particularly high energy storage densities can be achieved, which leads to further advantages, in particular in the field of electromobility.

Furthermore, a motor vehicle is provided which comprises the battery according to the invention. The battery is generally provided for feeding an electric drive system of the vehicle.

Advantageous developments of the invention are specified in the dependent claims and can be gleaned from the description.

### DRAWINGS

Exemplary embodiments of the invention will be explained in more detail with reference to the drawings and the following description. In the drawings:

FIG. 1 shows a battery cell, battery module and battery (prior art),

FIG. 2 shows a circuit according to the invention, wherein no test current I_{P} is superposed on the current I_{M} to be measured, and

FIG. 3 shows the circuit according to the invention, wherein a test current I_{P} is superposed on the current I_{M} to be measured.

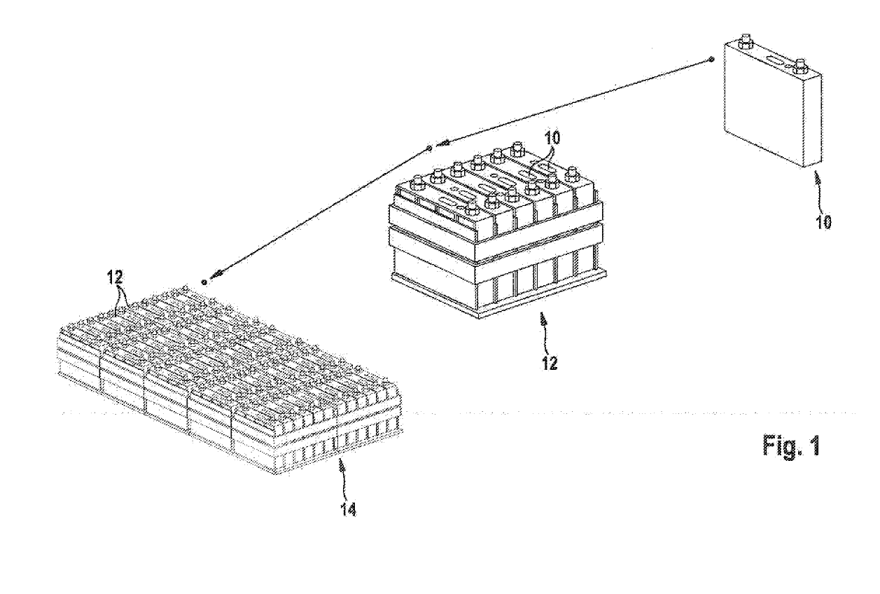

FIG. 1 has already been discussed to explain the prior art.

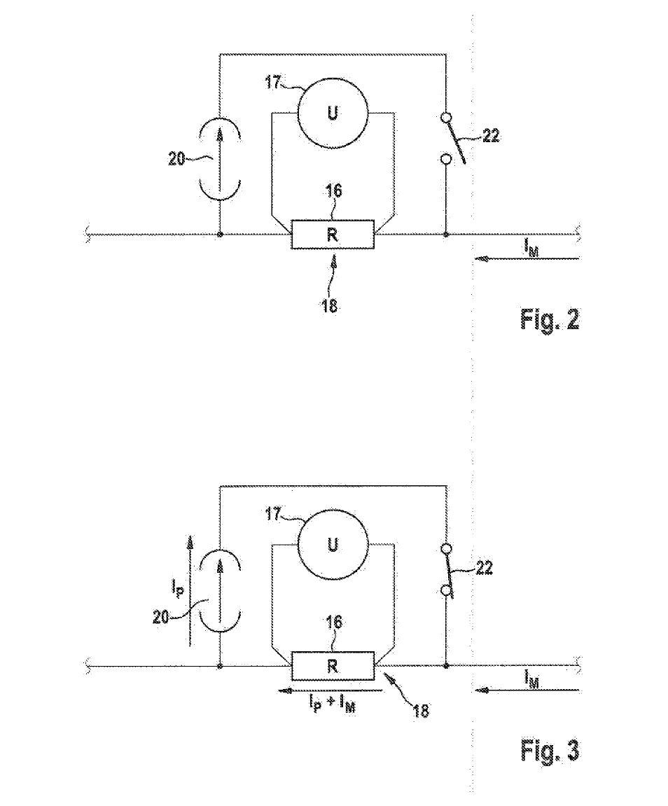

FIG. 2 shows a circuit according to the invention, wherein a current I_{M} to be measured which is flowing in an electrical conductor is detected by a means 18 for measuring the current. The means 18 for measuring the current can be implemented, as is conventional, by means of a measuring resistor 16 and an evaluation circuit 17. A current source 20 is electrically conductively connected, upstream and downstream of the means 18 for measuring the current, via a switching means 22 to the electrical conductor through which the current I_{M} to be measured is flowing.

In the normal measuring operation, the switching means 22 is open; no test current I_{P} is flowing. The means 18 for measuring the current therefore measures only the current I_{M} to be measured. This also serves as the first step of the method according to the invention. This occurs according to FIG. 2 by means of the measuring resistor 16 in combination with the evaluation circuit 17. The evaluation circuit 17 is able to amplify and evaluate even a small voltage drop which is used as measure for the flow of current through the measuring resistor 16.

The second and third steps of the method according to the invention are performed using a switch position of the switching means 22 as shown in FIG. 3. The switching means 22 is closed; a test current I_{P} of known magnitude is flowing via the switching means 22 and therefore through the measuring resistor 16.

25

A resultant current I_{Res} is measured by means of the measuring resistor 16 in combination with the evaluation circuit 17, which resultant current corresponds to the sum of the current I_{M} to be measured and the test current I_{P}. Provided that the current I_{M} to be measured when the switching means 22 is closed has the same level as the current I_{M} to be measured which is measured when the switching means 22 is open, the current measurement can now be checked. This is done by comparing the measured currents when the switching means is open and closed. Therefore, the resultant current I_{Res} measured when the switching means 22 is closed must correspond to the sum of the current I_{M} to be measured which is measured when the switching means 22 is open and the test current I_{P} of known magnitude. If this should not be the case, a malfunction of the means 18 for measuring the current can be assumed. However, it is worth considering that such a deviation also comes about when the current I_{M} to be measured when the switching means 22 is open does not correspond to the current I_{M} to be measured when the switching means 22 is closed.

1. A method for checking an electrical current measurement comprising:
(I) measuring a current I_{M} to be measured using a current measuring structure;
(II) superposing a test current I_{P} having a known magnitude on the current I_{M} to be measured to give a resultant current I_{Res}, wherein I_{Res}=I_{M}+I_{P};
(III) measuring the resultant current I_{Res} using the current measuring structure within a time span of step (II); and
(IV) checking whether the resultant current I_{Res} measured in step (III) corresponds to a sum of the current I_{M} measured in step (I) and the known magnitude of the test current I_{P} superposed in step (II).

2. The method as claimed in claim 1, further comprising:
providing a switching structure via which the test current I_{P} is conducted in steps (II) and (III).

3. The method as claimed in claim 2, further comprising:
detecting a the switching state of the switching structure from which a conclusion can be drawn in respect of a the flow of the test current I_{P}.

4. An electrical circuit for checking an electrical current measurement, comprising:
a current measuring structure configured to measure an electrical I_{M}; and
a current source configured to superpose, as required, a test current I_{P} having a of known magnitude on the current I_{M} to be measured such that the current measuring structure is configured to measure a resultant current I_{Res},
wherein I_{Res}=I_{M}+I_{P},
wherein the electrical circuit is configured to check the electrical current measurement according to a method including
(I) measuring the current I_{M} using the current measuring structure,
(II) superposing the test current I_{P} on the current I_{M} to give the resultant current I_{Res},
(III) measuring the resultant current I_{Res} using the current measuring structure within a time span of step (II), and
(IV) checking whether the resultant current I_{Res} measured in step (III) corresponds to a sum of the current I_{M} measured in step (I) and the known magnitude of the test current I_{P} superposed in step (II).

5. The electrical circuit as claimed in claim 4, further comprising:
a switching structure connected between the current source and the current measuring structure.

6. The electrical circuit as claimed in claim 5, wherein the switching structure includes a transistor.

7. The electrical circuit as claimed in claim 4, wherein the current measuring structure includes a measuring resistor with an evaluation circuit.

8. The electrical circuit as claimed in claim 4, wherein the electrical circuit is included in a battery.

9. A motor vehicle comprising:
a battery including an electrical circuit configured to check an electrical current measurement, the electrical circuit including (i) a current measuring structure configured to measure an electrical current I_{M}, and (ii) a current source configured to superpose, as required, a test current I_{P} having a known magnitude on the current I_{M} to be measured such that the current measuring structure is configured to measure a resultant current I_{Res},
wherein I_{Res}I_{M}+I_{P},
wherein the electrical circuit is configured to check the electrical current measurement according to a method including
(I) measuring the current I_{M} using the current measuring structure,
(II) superposing the test current I_{P} on the current I_{M} to give the resultant current I_{Res},
(III) measuring the resultant current I_{Res} using the current measuring structure within a time span of step (II), and
(IV) checking whether the resultant current I_{Res} measured in step (III) corresponds to a sum of the current I_{M} measured in step (I) and the known magnitude of the test current I_{P} superposed in step (II).
